(19) United States
(12) Patent Application Publication
(10) Pub. No.: US 2021/0005493 A1
(43) Pub. Date: Jan. 7, 2021

(54) PROCESSING APPARATUS

(71) Applicant: TOKYO ELECTRON LIMITED, Tokyo (JP)

(72) Inventors: Toshiaki FUJISATO, Nirasaki City, Yamanashi (JP); Tadahiro ISHIZAKA, Nirasaki City, Yamanashi (JP); Takashi MOCHIZUKI, Nirasaki City, Yamanashi (JP); Daisuke TORIYA, Nirasaki City, Yamanashi (JP)

(21) Appl. No.: 16/767,480

(22) PCT Filed: Oct. 12, 2018
(86) PCT No.: PCT/JP2018/038157

§ 371 Date: May 27, 2020

(30) Foreign Application Priority Data
Nov. 28, 2017 (JP) 2017-228011

(51) Int. Cl. H01L 21/683; H01L 21/67; C23C 16/455; C23C 16/458; H01L 21/285

(52) U.S. Cl. CPC H01L 21/6833; H01L 21/67023; H01L 21/285; C23C 16/458; C23C 16/45538

(57) ABSTRACT

When performing processing on a substrate in a plasma-free atmosphere, the substrate is reliably attracted to perform processing with high uniformity in the plane of the substrate. An apparatus includes a DC power source and a processing gas supply part. The DC power source has a positive electrode connected to one of an electrode of an electrostatic chuck and a conductive member, and a negative electrode connected to the other of the electrode and the conductive member, and attracts the substrate to a dielectric layer of the electrostatic chuck by electrostatic attraction force generated by applying voltage between the conductive member located at a processing position and the electrode in a state in which plasma is not formed inside a processing container. The processing gas supply part performs processing by supplying a processing gas to the substrate in a state in which the substrate is attracted to the dielectric layer.

### TECHNICAL FIELD

The present disclosure relates to a technique for use in a processing apparatus that performs processing by attracting a substrate with an electrostatic chuck.

### BACKGROUND

In a semiconductor device manufacturing process, a film is formed on a semiconductor wafer (hereinafter referred to as wafer) as a substrate by CVD (Chemical Vapor Deposition) or ALD (Atomic Layer Deposition). These film forming processes are performed by supplying a film-forming gas in a state in which the wafer mounted on a stage is heated to a predetermined temperature by a heater provided in the stage inside a processing container.

When the wafer is transferred into the aforementioned processing container, the wafer may be warped. If the warped wafer is mounted on the stage, it is difficult for the heat of the stage to be evenly radiated to respective portions in the plane of the wafer. Thus, the warpage may be further increased, or a film thickness in the plane of the wafer may become non-uniform as a result of the film-forming gas being supplied in a state in which the temperature is non-uniform in the plane of the wafer and a portion failing to reach a predetermined temperature is present in the plane of the wafer.

By the way, in an apparatus for performing a plasma process on a substrate, a front surface portion of a stage may be configured by an electrostatic chuck to electrostatically attract the substrate, and may be configured to prevent the temperature of the substrate from increasing due to the incidence of ions constituting plasma. For example, Patent Document 1 discloses an apparatus that presses a peripheral edge portion of an LCD glass substrate against a stage by a pressing mechanism and attracts the peripheral edge portion of the LCD glass substrate by an electrostatic chuck when performing plasma etching. In order to address the problem of wafer warpage described above, it is conceivable to apply the electrostatic chuck to a film forming apparatus. For example, Patent Document 2 discloses that an electrostatic chuck may be installed in a wafer film-forming apparatus provided with a pressing mechanism similar to that of Patent Document 1.

### PRIOR ART DOCUMENTS

### Patent Documents

Patent Document 1: Japanese laid-open publication No, 2004-55585

Patent Document 2: Japanese laid-open publication No. 2001-53030

The electrostatic chuck disclosed in Patent document 1 is a so-called mono-polar electrostatic chuck in which only an electrode applied with one of a positive voltage and a negative voltage from a DC power source is used as an electrode (chuck electrode) for attracting a substrate by polarizing a dielectric material constituting a front surface portion of the electrostatic chuck. In this mono-polar electrostatic chuck, plasma formed in a processing container is used as a conductive path so that the other of the positive voltage and the negative voltage is applied to the substrate from the DC power source. That is, in an atmosphere where plasma is not formed, the aforementioned polarization does not occur, which snakes it impossible to attract the substrate. However, the aforementioned film forming process may sometimes be performed in an atmosphere in which plasma is not formed.

In addition, as the electrostatic chuck, there is known a so-called bipolar electrostatic chuck in which an electrode applied with a positive voltage from a DC power source and an electrode applied with a negative voltage from the DC power source are provided as chuck electrodes so that the formation of plasma becomes unnecessary. In Patent Document 2 mentioned above, it is considered that the bipolar electrostatic chuck is provided because no plasma is formed in the processing container. However, in the aforementioned film forming process using. CVD or ALD, a film-forming gas supplied to a front surface of the wafer flows to a back surface via the side of the wafer. Thus, there is a concern that a film is formed in a gap between the back surface of the wafer and the electrostatic chuck. When a metal film is formed on a wafer, the film formed in the gap serves as a conductive path that electrically connects a plurality of chuck electrodes, whereby polarization does not occur between the back surface of the water and the electrostatic chuck. Thus, there is a concern that the wafer is not attracted to the electrostatic chuck. Patent Document 2 does not disclose a solution to this problem.

The present disclosure provides some embodiments of a technique capable of, when processing is performed on a substrate in an atmosphere in which no plasma is formed, attracting the substrate with high reliability and performing the processing with high uniformity in the plane of the substrate.

### SUMMARY

According to one embodiment of the present disclosure, there is provided a processing apparatus, including: an electrostatic chuck provided inside a processing container in which a vacuum atmosphere is formed, the electrostatic chuck including an electrode and a dielectric layer that covers the electrode, the dielectric layer having a front surface side forming an attraction region for a substrate; a conductive member provided on the front surface side of the dielectric layer; an elevating mechanism configured to raise and lower the electrostatic chuck relative to the conductive member such that the electrostatic chuck is positioned in a processing position at which the conductive member comes into contact with the substrate and a standby position at which the substrate is transferred to the electrostatic chuck; a DC power source having a positive electrode connected to one of the electrode and the conductive member and a negative electrode connected to the other of the electrode and the conductive member, the DC power source configured to attract the substrate to the dielectric layer by virtue of an electrostatic attraction force generated by applying a voltage between the conductive member located at the processing position and the electrode in a state where plasma is not formed inside the processing container; and a processing gas supply part configured to process the substrate by supplying a processing gas to a front surface of the substrate in a state in which the substrate is attracted to the dielectric layer.

According to the present disclosure, the positive electrode side and the negative electrode side of the DC power source are respectively connected to one and the other of the electrode constituting the electrostatic chuck and the conductive member, and a voltage is applied between the electrode of the electrostatic chuck and the conductive member. The processing gas is supplied to perform processing in a state in which the substrate is attracted to the electrostatic chuck by virtue of the electrostatic attraction force thus generated. According to such a configuration, it is possible to perform the processing by reliably attracting the substrate to the electrostatic chuck in a state in which plasma is not formed in the processing container. As a result, it is possible to enhance the uniformity of the processing in the plane of the substrate.

### BRIEF DESCRIPTION OF DRAWINGS

FIG. 1 is a longitudinal sectional view of a film forming apparatus as an example of a processing apparatus according to the present disclosure.

FIG. 2 is a longitudinal sectional view of the film forming apparatus.

FIG. 3 is a top view of a clamp ring constituting the film forming apparatus.

FIG. 4 is a schematic view showing a longitudinal cross section of an electrostatic chuck constituting a stage of the film forming apparatus.

FIG. 5 is a longitudinal sectional view of the stage provided in the film forming apparatus.

FIG. 6 is a longitudinal sectional view of a film forming apparatus having another configuration according to the present disclosure.

### DETAILED DESCRIPTION

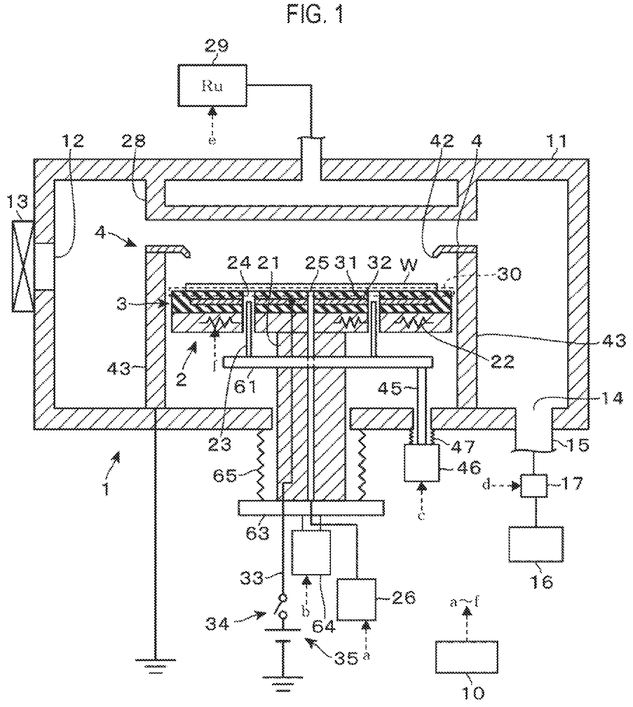

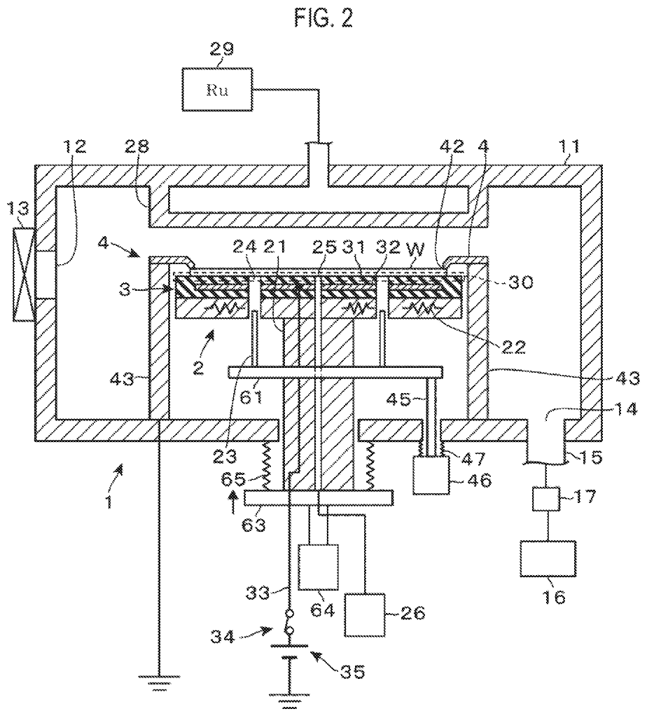

A film forming apparatus I according to an embodiment of a processing apparatus of the present disclosure will be described with reference to the longitudinal sectional views of FIGS. 1 and 2, The film forming apparatus 1 is configured to attract a wafer W, which is a circular substrate made of, for example, silicon, by an electrostatic chuck, and is configured to perform CVD by supplying a film-forming gas in a state in which a clamp ring described later makes contact with a peripheral edge portion of the wafer W. By this CVD, a ruthenium (Ru) film, which is a metal film, is formed on a front surface of the wafer W.

The film forming apparatus 1 includes a processing container 11. No plasma is formed inside the processing container 11. The processing container 11 is grounded to a GND (ground). In the figures, reference numeral 12 denotes a transfer port for the wafer W opened in the side wall of the processing container 11. The transfer port 12 is opened and closed by a gate valve 13. An exhaust port 14 is opened at the bottom of the processing container 11, and is connected to a vacuum pump 16 via an exhaust pipe 15. In the figures, reference numeral 17 denotes a pressure regulation part constituted by a valve and the like provided in the exhaust pipe 15. The pressure regulation part 17 adjusts the amount of exhaust from the exhaust port 14 and adjusts the inside of the processing container 11 to a vacuum atmosphere of a desired pressure.

A horizontal circular stage 2 for the wafer W is provided inside the processing container 11. A front surface portion (upper surface portion) of the stage 2 is configured by a flat circular electrostatic chuck 3. The electrostatic chuck 3 has been described as a mono-polar electrostatic chuck in the Background section of the present disclosure. The electrostatic chuck 3 includes a main body portion 31, which is a dielectric body, and an electrode 32 embedded in the main body portion 31. Since the electrode 32 is embedded in this manner, a dielectric layer 30 is provided above the electrode 32 so as to cover the electrode 32. In addition, dielectric layers are provided below and beside the electrode 32.

The wafer W is mounted on the front surface of the electrostatic chuck 3 such that the center of the wafer W overlaps the center of the main body portion 31. As will be described. later, the diameter of the main body portion 31 is set larger than that of the wafer W in order to attract the entire back surface of the mounted wafer W.

One end of a conductive wire 33 is connected to the electrode 32. The other end of the conductive wire 33 extends downward through a column 21 of the stage 2. The other end of the conductive wire 33 is connected to a positive electrode side of a DC power source 35 provided outside the processing container 11 via a switch 34 provided outside the processing container 11. A negative electrode side of the DC power source 35 is connected to the ground.

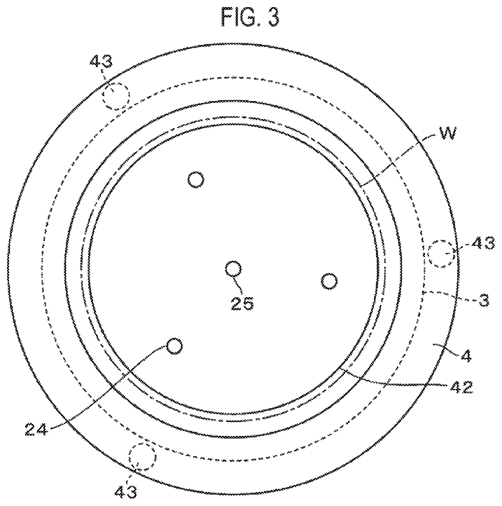

A clamp ring 4 as an annular member is provided above (the front surface side of) the electrostatic chuck 3. Description will be continued with reference to FIG. 3 which shows an upper surface of the clamp ring 4. The clamp ring 4 has a contact portion 42 provided at an inner end thereof. The contact portion 42 is located slightly inward of the peripheral edge of the wafer W mounted on the electrostatic chuck 3, and is formed along the peripheral edge of the wafer W in a plan view. The clamp ring 4 comes into contact with the peripheral edge of the wafer W by the contact portion 42 and serves as a conductive path for attracting the wafer W to the electrostatic chuck 3 as described later. The clamp ring 4 is formed of a conductive member so as to function as the conductive path.

Support pillars 43 extend downward from the peripheral edge portion of the clamp ring 4. For example, three support pillars 43 are provided at intervals in the circumferential direction of the clamp ring 4 so as not to hinder the delivery of the wafer W to the electrostatic chuck 3. Lower ends of the support pillars 43 are supported on the bottom surface of the processing container 11. The support pillars 43 are also configured as conductive paths just like the clamp ring 4.

As described later, the electrostatic chuck 3 is configured to be able to move up and down. When the wafer W is delivered between a transfer mechanism (not shown) that transfers the wafer W in and out of the processing container 11 and the electrostatic chuck 3. the electrostatic chuck 3 is located in a standby position (transfer position) shown in FIG. 1 so as not to hinder the delivery. When the wafer \V mounted on the electrostatic chuck 3 is processed, the electrostatic chuck 3 is located at a processing position shown in FIG. 2. When the electrostatic chuck 3 is located at the processing position, the contact portion 42 of the clamp ring 4 conies into contact with the peripheral edge of the wafer W over the entire circumference of the wafer W. The lower ends of the support pillars 43 are connected to the bottom portion of the processing container 11 and connected to the ground.

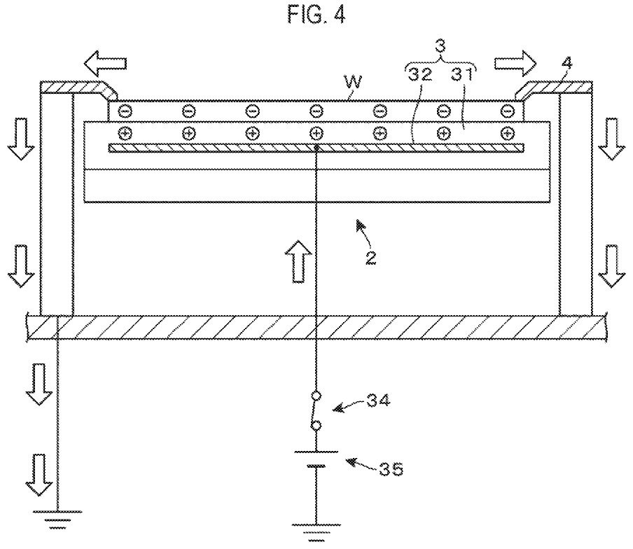

Incidentally, the electrostatic chuck 3 is a Johnsen-Rahbek type electrostatic chuck, and attracts the wafer W by virtue of a Johnsen-Rahbek force. When the electrostatic chuck 3 is located at the processing position, the switch 34 is turned on so that a potential difference is formed between the electrode 32 of the electrostatic chuck 3 and the clamp ring 4. An electric current flows between the electrode 32 and the clamp ring 4. The Johnsen-Rahbek force of the electrostatic chuck 3 acts to attract the wafer W to the electrostatic chuck 3. More specifically, the wafer W and the electrode 32 of the electrostatic chuck 3 mutually function as the counter electrodes of a capacitor, and performs polarization over the entire surface with the dielectric layer 30 interposed therebetween, thereby attracting the whole surface of the wafer W to the electrostatic chuck 3. In FIG. 4, the arrows schematically indicate the flow of a current between the electrode 32 and the clamp ring 4 and indicate the polarity of the back surface of the wafer W and the polarity of the front surface of the dielectric layer 30. Specifically, in order to obtain the action of the Johnsen-Rahbek force, the main body portion 31 is configured such that, for example, the volume resistivity is 1 E⁹ ω·cm to 1 E¹¹ ω·cm in a temperature band in which the electrostatic chuck 3 is used.

Description will be continued with reference to FIGS. 1 to 3. A heater 22 is embedded in the stage 2 below the electrostatic chuck 3, and the front surface of the electrostatic chuck 3 is heated to a desired temperature by the heater 22. Furthermore, three lift pins 23 are inserted into through-holes 24 formed in the stage 2 so as to be opened on the front surface of the electrostatic chuck 3. in the drawings, reference numeral 61 denotes a horizontal plate for supporting the lift pins 23, and reference numeral 45 denotes a support rod having an upper end connected to the horizontal plate 61. A lower end of the support rod 45 extends outward of the processing container 11 and is connected to a lifting mechanism 46. In the drawings, reference numeral 47 denotes a bellows that surrounds the support rod 45 outside the processing container 11. The bellows 47 is provided so as to ensure airtightness of the interior of the processing container 11.

in the drawings, reference numeral 25 denotes a gas discharge hole opened at the center of the front surface of the electrostatic chuck 3. The gas discharge hole 25 is connected to a gas source 26 via gas supply paths provided in the stage 2 and the column 21. The gas supplied from the gas source 26 and discharged from the gas discharge hole 25 is a gas for transferring the heat of the electrostatic chuck 3 heated by the heater 22 to the wafer W. The gas is, for example, a He (helium) gas. Hereinafter, such a He gas discharged from the gas discharge hole 25 may be described as a heat transfer gas. Furthermore, the column 21 supporting the stage 2 is supported on an elevating table 63 provided outside the processing container 11 via a through-hole opened on the bottom surface of the processing container 11. The elevating table 63 is configured to be moved up and down by an elevating mechanism 64. That is, in the film forming apparatus 1, the stage 2 is configured to be able to move up and down. In the drawings, reference numeral 65 denotes a bellows which surrounds the lower end portion of the column 21 for supporting the stage 2. The bellows 65 is provided to keep the processing container 11 airtight.

A film-forming gas supply part 28, which is a processing gas supply part that supplies a film-forming gas as a processing gas into the processing container 11, is provided on the ceiling of the processing container 11 so as to face the stage 2. In the drawings, reference numeral 29 denotes a film-forming gas source which supplies the film-forming gas for forming a Ru for example, a gas containing ruthenium carbonyl [Ru₃(CO)₁₂], to the film-forming gas supply part 28.

Furthermore, the film forming apparatus 1 includes a controller 10. The controller 10 includes a computer, and includes a program, a memory and a CPU. The program incorporates a group of steps for causing a series of operations described below to execute the film forming apparatus 1. The controller 10 outputs a control signal to each part of the film forming apparatus 1 according to the program, whereby the operation of each part is controlled. Specifically, the respective operations such as the supply of each gas from the film-forming gas source 29 and the heat transfer gas source 26, the adjustment of the internal pressure of the processing container 11 by the pressure regulation part 17, the elevation of the stage 2 by the elevating mechanism 64, the lifting of the lift pins 23 by the lifting mechanism 46, the adjustment of the temperature of the wafer W by adjusting the heat generation amount of the heater 22, the turning on/off of the switch 34, and the like are controlled by respective control signals. The above program is stored in a storage medium such as a compact disk, a hard disk, a magneto-optical disk, a DVD or the like, and is installed on the controller 10.

The wafer W is mounted on the electrostatic chuck 3 located at the standby position shown in FIG, 1 through the lift pins 23. By moving the electrostatic chuck 3 to the processing position shown in FIG. 2, bringing the clamp ring 4 into contact with the wafer W, and turning on the switch 34, the wafer W is attracted onto the electrostatic chuck 3. As the wafer W is attracted onto the electrostatic chuck 3, heat is transferred from the electrostatic chuck 3 heated by the heater 22 to the wafer W. Moreover, the heat transfer gas is discharged from the gas discharge hole 25 of the electrostatic chuck 3 to the back surface of the wafer W. The heat transfer gas flows through a minute gap between the back surface of the wafer W and the electrostatic chuck 3. The heat of the electrostatic chuck 3 is also transferred to the wafer W through the heat transfer gas. As described above, the entire back surface of the wafer W is attracted onto the electrostatic chuck 3 and is filled with the heat transfer gas. Therefore, the wafer W is heated with high in-plane uniformity. As a result, the temperature can be raised with high uniformity at the respective portions in the plane of the wafer W. The film-forming gas is supplied from the film-forming gas supply part 28. Ruthenium carbonyl constituting the film-forming gas is decomposed by heat on the front surface of the wafer W, whereby a Ru film is formed on the front surface of the wafer W.

In addition, the film forming process for Ru film is performed While keeping the internal pressure of the processing container 11 relatively low. In the case of such a process in which the film formation pressure is low, the heat of the stage is not easily transferred to the wafer W. The configuration of the wafer attraction, the heat transfer gas and the clamp ring in the above-described film forming apparatus 1 has an advantage that the film can be formed by more reliably setting the temperature of the wafer W to a desired temperature. When the Ru film has a predetermined thickness, the supply of the film-forming gas from the film-forming gas supply part 28 and the discharge of the heat transfer gas from the gas discharge hole 25 are stopped to terminate the film forming process. The wafer W is unloaded from the processing container 11 in a procedure opposite the procedure performed when the wafer W is loaded into the processing container 11.

According to the film forming apparatus 1, the electrostatic chuck 3 supporting the back surface of the wafer W and the electrode 32 constituting the clamp ring 4 in contact with the front surface of the peripheral edge portion of the wafer W are respectively connected to the positive electrode and the negative electrode of the DC power source 35. By the electrostatic attraction force generated by applying a voltage between the electrode 32 and the clamp ring 4, the wafer W is attracted onto the electrostatic chuck 3 in an atmospheric condition in which no plasma is formed, Thus, the wafer W is heated so that the temperature uniformity in the plane of the wafer W is enhanced. Therefore, the Ru film is formed at a thickness having high uniformity in the plane of the wafer W. As a result, it is possible to enhance the yield of the semiconductor products manufactured from the wafer W.

The processing position of the clamp ring 4 when processing the wafer W may be a position where the clamp ring 4 makes contact with the wafer W, or may be a position where the clamp ring 4 makes contact with the wafer W and presses the wafer W. By setting the processing position to the position where the clamp ring 4 presses the wafer W, the peripheral edge portion of the wafer W is reliably brought into contact with the electrostatic chuck 3 by the pressing force and the attraction action of the electrostatic chuck 3, whereby heat is transferred from the electrostatic chuck 3 heated by the heater 22 to the peripheral edge portion of the wafer W. That is, it is possible to more reliably prevent the peripheral edge portion of the wafer W from floating upward from the electrostatic chuck 3 and to suppress a decrease in the temperature of the peripheral edge portion of the wafer W.

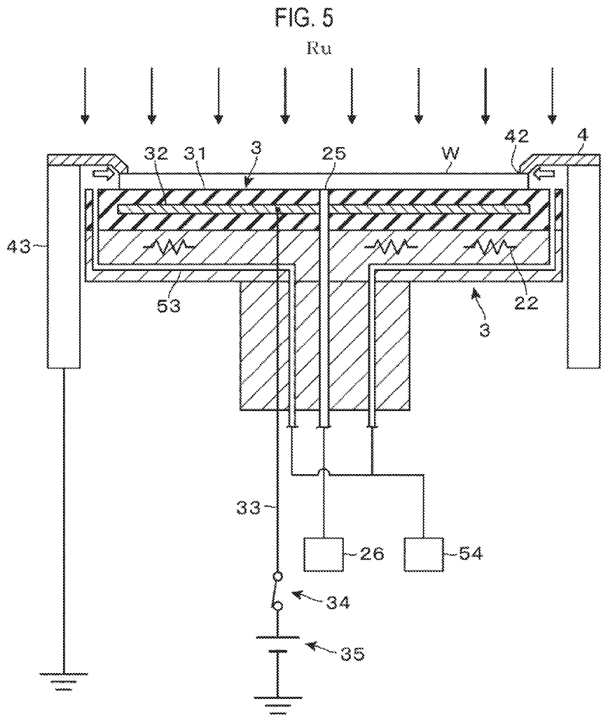

FIG. 5 shows an example in which one end of a flow path 53 is opened on the peripheral edge portion of the electrostatic chuck 3 below the clamp ring 4. The other end of the flow path 53 is connected to a CO gas source 54 that supplies, for example, a CO (carbon monoxide) gas as a film-formation suppressing gas. The film-formation suppressing gas supplied onto the peripheral edge portion of the electrostatic chuck 3 below the clamp ring 4 via the flow path 53 can suppress formation of a film at a point where the wafer W and the contact portion 42 of the clamp ring 4 come into contact with each other.

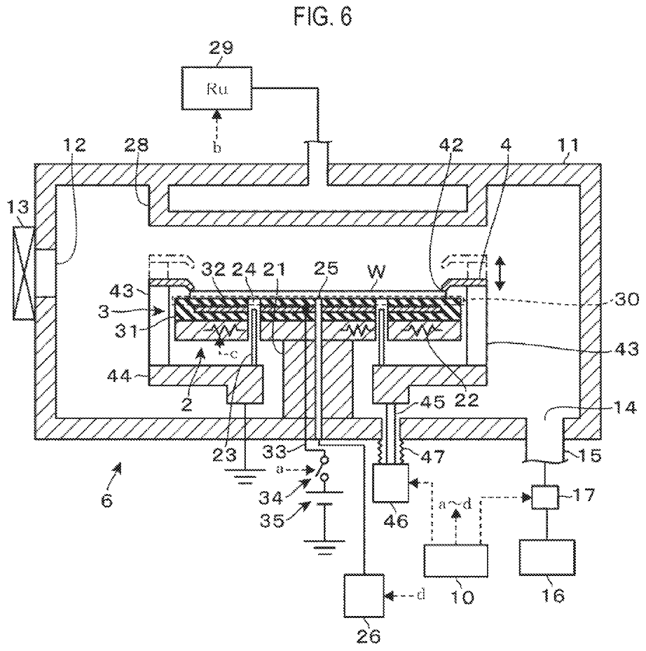

Next, a film forming apparatus 6 which is a modification of the film forming apparatus 1 will be described with reference to FIG. 6 by focusing on differences from the film forming apparatus 1. The lower ends of the support pillars 43 supporting the clamp ring 4 are supported. on the outer edge portion of a horizontal annular lowering member 44 provided so as to surround the column 21 supporting the stage 2. The inner edge portion of the lower ring member 44 is located below the peripheral edge portion of the stage . The lower ring member 44 is also configured as a conductive path. Furthermore, the lower ring member 44 is connected to a lifting mechanism 46 via a support rod 45. The lift pins 23 are supported by the lower ring member 44 instead of being supported by the support plate 61. Accordingly, the clamp ring 4 and the lift pins 23 are raised and lowered together by the lifting mechanism 46.

The clamp ring 4 moves up and down between a position indicated by a solid line in FIG. 6 and a position indicated by a chain line in FIG. 6. The position indicated by the solid line is a position where the clamp ring 4 comes into contact with the wafer W and the wafer W is attracted onto the electrostatic chuck 3. When viewed from the clamp ring 4, the electrostatic chuck 3 is located at the processing position mentioned in the description of the film forming apparatus 1. The position indicated by the chain line is the position of the clamp ring 4 when the wafer W is transferred between the transfer mechanism and the lift pins 23. When viewed from the clamp ring 4, the electrostatic chuck 3 is located at the standby position described above. As in the film forming apparatuses 1 and 6, the electrostatic chuck 3 may be moved up and down relatively to the clamp ring 4. Any one of the electrostatic chuck 3 and the clamp ring 4 may be moved up and down. The clamp ring 4 only needs to be electrically connected to the DC power source 34 and the ground. The conductive path for making this connection is not limited to being configured by the support pillars 43 and the lower ring member 44.

The film formed by the film forming apparatus I using the film-forming gas is not limited to the Ru film. The film forming apparatus I may be used for forming other conductive films having conductivity. These conductive films are films other than an insulating film, and include a metal film. Specifically, a metal film composed of, for example, Cu (copper), Ti (titanium), W (tungsten), Al (aluminum) or the like may be formed. Furthermore, the conductive film includes a semiconductor film of Si (silicon) or the like and a conductive film of carbon or the like having conductivity. Moreover, as the film forming apparatus, any film forming apparatus may be used as long as it can form a film on a substrate by supplying a film-forming gas to the substrate in an atmosphere in which no plasma is formed. Therefore, the present disclosure is not limited to the apparatus for forming the film by CVD. The film forming apparatus may be configured as an apparatus for forming a film on a substrate by ALD by alternately and repeatedly supplying a raw material gas and a reaction gas reacting with the raw material gas into the processing container 11, Specifically, the film forming apparatus may be configured as, for example, a film forming apparatus for forming a TiN (titanium nitride) film by ALD by supplying a TiCl₄ (titanium tetrachloride) gas as a raw material gas and an NH₃ (ammonia) gas as a reaction gas. In the film forming apparatus 1, the entire back surface of the wafer W is attracted as described above, and the heat transfer gas is allowed to flow under the entire back surface of the wafer W. Accordingly, a conductive film is hardly formed on the back surface of the wafer W. This makes it possible to suppress the loss of the attraction force for the wafer W due to the formation of the conductive film. Therefore, the film forming apparatus I is particularly effective when forming the conductive film on the front surface of the wafer W. However, the film forming apparatus I may also be applied to a case where an insulating film such as a SiO₂ (silicon oxide) film or the like is formed on the wafer W. Furthermore, the processing apparatus of the present technique is not limited to being configured as a film forming apparatus, and may be configured as, for example, an etching apparatus that performs etching by supplying an etching gas as a processing gas to a wafer W. In the above example, the clamp ring 4, i.e., the annular member is used as the conductive member provided on the front surface side of the electrostatic chuck 3. However, as the conductive member, any configuration may be used as long as it can make contact with the wafer W to generate an electrostatic attraction force in an atmosphere in which no plasma is formed as described above. That is, the conductive member may have any shape, and the shape of the conductive member is not limited to the annular shape.

In addition, it is only necessary that a potential difference is formed between the clamp ring 4 and the electrode 32 of the electrostatic chuck 3 to supply electric power to the electrostatic chuck 3. Therefore, the scope of the present disclosure encompasses a case where the positive and negative electrodes of the DC power source 35 are not connected to the ground. The present disclosure is not limited to the exemplary configurations described above. The above-described embodiments may be appropriately modified or combined.

### EXPLANATION OF REFERENCE NUMERALS

W: wafer, 1: film forming apparatus, 10: controller, 11: processing container, 2: stage, film-forming gas supply part. 3: electrostatic chuck, 31: electrode, 32: main body portion, 35: DC power source, 4: clamp ring

What is claimed is:

1. A processing apparatus, comprising:
an electrostatic chuck provided inside a processing container in which a vacuum atmosphere is formed, the electrostatic chuck including an electrode and a dielectric layer that covers the electrode, the dielectric layer having a front surface side forming an attraction region for a substrate;
a conductive member provided on the front surface side of the dielectric layer;
an elevating mechanism configured to raise and lower the electrostatic chuck relative to the conductive member such that the electrostatic chuck is positioned in a processing position at which the conductive member comes into contact with the substrate and a standby position at which the substrate is transferred to the electrostatic chuck;
a DC power source having a positive electrode connected to one of the electrode and the conductive member and a negative electrode connected to the other of the electrode and the conductive member, the DC power source configured to attract the substrate to the dielectric layer by virtue of an electrostatic attraction force generated by applying a voltage between the conductive member located at the processing position and the electrode in a state where plasma is not formed inside the processing container; and
a processing gas supply part configured to process the substrate by supplying a processing gas to a front surface of the substrate in a state in which the substrate is attracted to the dielectric layer.

2. The apparatus of claim 1, wherein the conductive member is an annular member having an inner edge portion formed along a peripheral edge portion of the substrate.

3. The apparatus of claim 1, wherein the processing gas is a film-forming gas for forming a film on the substrate.

4. The apparatus of claim 3. wherein the film-forming gas is a gas for forming a conductive film on the substrate.

5. The apparatus of claim 1, wherein the processing position is a position at which a peripheral edge portion of the substrate is brought into contact with the electrostatic chuck and pressed against the electrostatic chuck by the conductive member.

6. The apparatus of claim 1, wherein the electrode includes only an electrode connected to one of the positive electrode and the negative electrode of the DC power source.

7. The apparatus of claim 3, wherein a gas discharge part configured to supply a film-formation suppressing gas onto a peripheral edge portion of the electrostatic chuck below the conductive member is provided to suppress a film from being formed between the conductive member and the substrate.
